(19) United States
(12) Patent Application Publication
(10) Pub. No.: US 2024/0379620 A1
(43) Pub. Date: Nov. 14, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventor: Dahee PARK, Suwon-si (KR)

(21) Appl. No.: 18/418,765

(22) Filed: Jan. 22, 2024

(30) Foreign Application Priority Data
May 12, 2023 (KR) 10-2023-0061602

(51) Int. Cl. H01L 25/065; H01L 23/00; H01L 23/31; H01L 25/18

(52) U.S. Cl. CPC H01L 25/0657; H01L 23/3128; H01L 24/32; H01L 24/48; H01L 24/73; H01L 25/18; H01L 2224/32145; H01L 2224/32225; H01L 2224/48227; H01L 2224/73265; H01L 2225/06562; H01L 2924/1431

(57) ABSTRACT

A semiconductor package includes a package substrate. A first semiconductor chip is arranged on the package substrate. A second semiconductor chip is disposed on the first semiconductor chip by an adhesive film. The second semiconductor chip is offset-aligned with the first semiconductor chip in a horizontal direction. A stress relieving adhesive layer is disposed on the first semiconductor chip and covers an upper surface of the first semiconductor chip. The stress relieving adhesive layer extends vertically downward from the upper surface to cover a side surface of the first semiconductor chip under an overhang region of the second semiconductor chip. A molding member covers the first semiconductor chip and the second the semiconductor chip on the package substrate.

### CROSS-REFERENCE TO RELATED APPLICATION

This application claims priority under 35 U.S.C. § 119 to Korean Patent Application No. 10-2023-0061602, filed on May 12, 2023 in the Korean Intellectual Property Office, the disclosure of which is incorporated by reference in its entirety herein.

### 1. TECHNICAL FIELD

Embodiments of the present disclosure relate to a semiconductor package and a method of manufacturing the semiconductor package. More particularly, embodiments of the present disclosure relate to a semiconductor package including a plurality of different chips stacked on a package substrate and a method of manufacturing the semiconductor package.

### 2. DISCUSSION OF RELATED ART

In a multi-chip package (MCP), a plurality of semiconductor chips may be sequentially attached on a package substrate using an adhesive film such as a die attach film (DAF) through a die attach process. The plurality of semiconductor chips may be stacked in a zigzag or cascade arrangement. With these arrangements, each of an upper chip and a lower chip may have an overhang region that protrudes from one side portion of the corresponding one of the upper chip and the lower chip. A triple point where three different materials meet may occur in an upper side surface of the lower chip under the overhang region of the upper chip or an upper side surface of the overhang region of the lower chip. Thus, an edge peeling-off failure due to a difference in hygroscopic expansion may occur in the triple point.

### SUMMARY

Embodiments of the present disclosure provide a semiconductor package capable of preventing an edge peeling-off and having increased reliability.

Embodiments provide a method of manufacturing the semiconductor package.

According to an embodiment of the present disclosure, a semiconductor package, includes a package substrate. A first semiconductor chip is arranged on an upper surface of the package substrate. The first semiconductor chip has a first side surface and a second side surface each extending in a first direction parallel to the upper surface of the package substrate and facing each other. The first semiconductor chip has first chip pads that are disposed on a first surface thereof and are arranged along the first side surface. A stress relieving adhesive layer is disposed on the first semiconductor chip and covers the first semiconductor chip from the first surface of the first semiconductor chip to the second side surface of the first semiconductor chip and exposes the first chip pads. A second semiconductor chip is disposed on the stress relieving adhesive layer on the first semiconductor chip by an adhesive film. The second semiconductor chip is offset-aligned with the first semiconductor chip in a second direction perpendicular to the first direction to expose the first chip pads. A molding member covers the first semiconductor chip and the second semiconductor chip on the package substrate.

According to an embodiment of the present disclosure, a semiconductor package includes a package substrate. A first semiconductor chip is arranged on the package substrate. A second semiconductor chip is disposed on the first semiconductor chip by an adhesive film. The second semiconductor chip is offset-aligned with the first semiconductor chip in a horizontal direction. A stress relieving adhesive layer is disposed on the first semiconductor chip and covers an upper surface of the first semiconductor chip. The stress relieving adhesive layer extends vertically downward from the upper surface to cover a side surface of the first semiconductor chip under an overhang region of the second semiconductor chip. A molding member covers the first semiconductor chip and the second the semiconductor chip on the package substrate.

According to an embodiment of the present disclosure, a semiconductor package includes a package substrate. A first semiconductor chip is arranged on the package substrate. The first semiconductor chip has first chip pads that are disposed on a first surface thereof and are arranged along a first side surface of the first semiconductor chip. A stress relieving adhesive layer covers the first surface of the first semiconductor chip except for the first chip pads and extends vertically downward to cover a second side surface facing the first side surface of the first semiconductor chip. A second semiconductor chip is disposed on the stress relieving adhesive layer on the first semiconductor chip by an adhesive film. The second semiconductor chip is offset-aligned with the first semiconductor chip in a horizontal direction from the first side surface to the second side surface such that the first chip pads are exposed by the second semiconductor chip. A molding member covers the first semiconductor chip and the second semiconductor chip on the package substrate. The stress relieving adhesive layer has a thickness in a range of about 10 μm to about 30 μm. The adhesive film has a thickness in a range of about 10 μm to about 40

According to embodiments of the present disclosure, in a method of manufacturing a semiconductor package, a first semiconductor chip is arranged on a package substrate. A mask is formed on an upper surface of the first semiconductor chip to cover first chip pads. A liquid adhesive is dispensed on a surface of the first semiconductor chip exposed by the mask to form a stress relieving adhesive layer that covers the upper surface and a side surface of the first semiconductor chip. The mask is removed from the upper surface of the first semiconductor chip. A second semiconductor chip is attached on the stress relieving adhesive layer on the upper surface of the first semiconductor chip by an adhesive film to be offset-aligned in a horizontal direction on the first semiconductor chip. The first chip pads of the first semiconductor chip and second chip pads of the second semiconductor chip are electrically connected to substrate pads of the package substrate using conductive connection members. A molding member is formed on the package substrate to cover the first semiconductor chip and the second semiconductor chip.

According to embodiments of the present disclosure, a semiconductor package may include a first semiconductor chip arranged on a package substrate, a second semiconductor chip offset-aligned in a horizontal direction on the first semiconductor chip by an adhesive film, a stress relieving adhesive layer covering an upper surface of the first semiconductor chip and extending vertically downward from the upper surface of the first semiconductor chip to cover a side surface of the first semiconductor chip under an overhang region of the second semiconductor chip, and a molding member covering the first semiconductor chip and the second semiconductor chip on the package substrate.

The stress relieving adhesive layer may cover the side surface of the first semiconductor chip under the overhang region of the second semiconductor chip. Additionally, the stress relieving adhesive layer may cover an upper edge portion of an overhang region of the first semiconductor chip adjacent to the adhesive film.

Accordingly, since the side surface of the first semiconductor chip or the upper edge portion of the upper surface of the first semiconductor chip is not in direct contact with the EMC material of the molding member, an edge peeling-off failure due to the difference in amount of hygroscopic expansion at the portion where different materials meet may be prevented.

### BRIEF DESCRIPTION OF THE DRAWINGS

Embodiments of the present disclosure will be more clearly understood from the following detailed description taken in conjunction with the accompanying drawings.

FIGS. 1 to 31 represent non-limiting embodiments as described herein.

FIG. 1 is a plan view illustrating a semiconductor package in accordance with an embodiment of the present disclosure.

FIG. 2 is a cross-sectional view taken along line A-A′ of FIG. 1 in accordance with an embodiment of the present disclosure.

FIG. 3 is a cross-sectional view taken along line B-B′ of FIG. 1 in accordance with an embodiment of the present disclosure.

FIG. 4 is a cross-sectional view taken along the line C-C′ of FIG. 1 in accordance with an embodiment of the present disclosure.

FIG. 5 is a cross-sectional view taken along the line B-B′ in FIG. 1 in accordance with a comparative embodiment.

FIG. 6 is a cross-sectional view taken along the line C-C′ of FIG. 1 in accordance with a comparative embodiment.

FIGS. 7 to 21 are views illustrating a method of manufacturing a semiconductor package in accordance with embodiments of the present disclosure.

FIGS. 5 to 19 are views illustrating a method of manufacturing a semiconductor package in accordance with embodiments of the present disclosure.

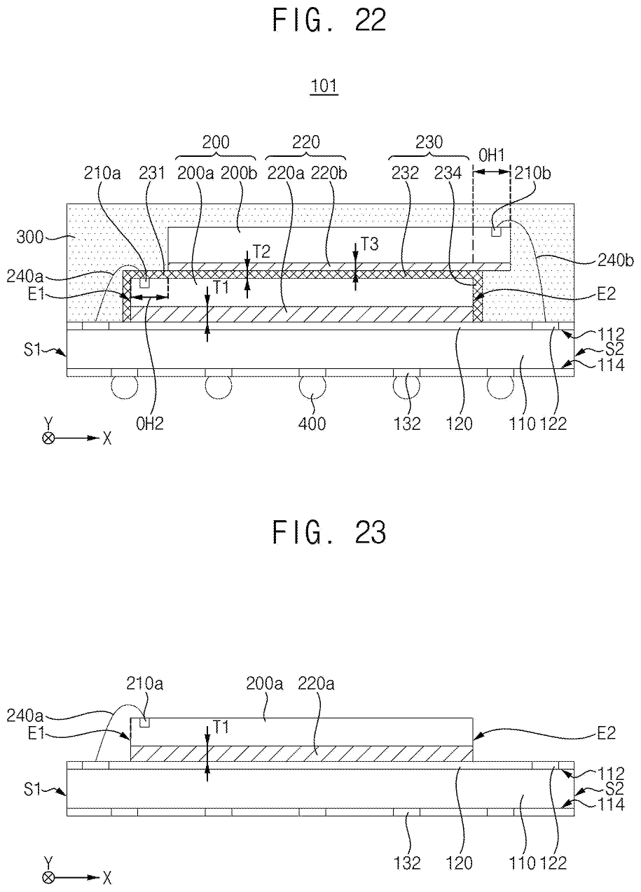

FIG. 22 is a cross-sectional view illustrating a semiconductor package in accordance with an embodiment of the present disclosure.

FIGS. 23 to 25 are cross-sectional views illustrating a method of manufacturing a semiconductor package in accordance with embodiments of the present disclosure.

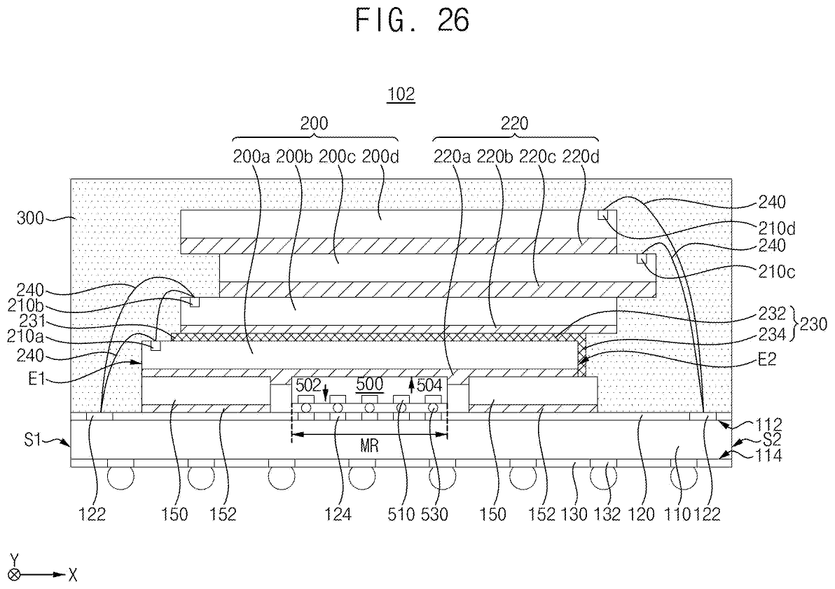

FIG. 26 is a cross-sectional view illustrating a semiconductor package in accordance with an embodiment of the present disclosure.

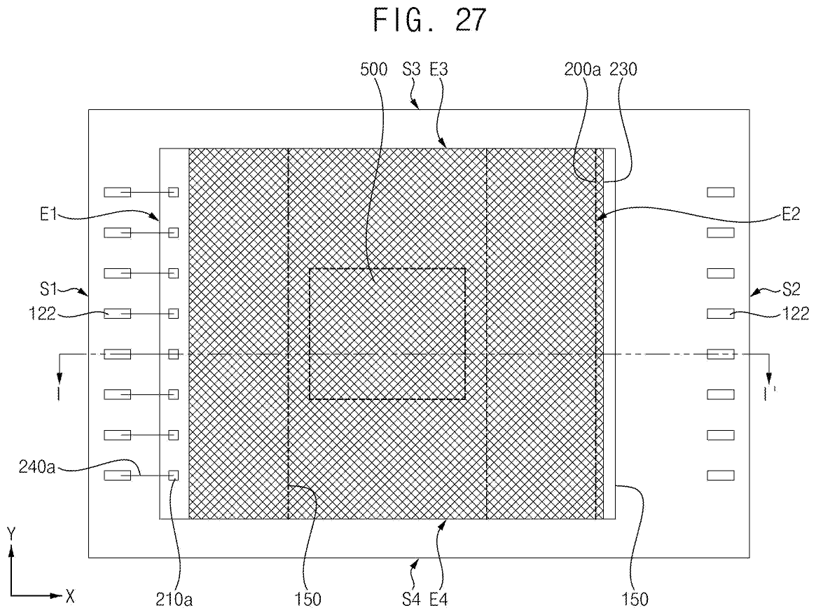

FIG. 27 is a plan view illustrating the semiconductor package in FIG. 26 in accordance with an embodiment of the present disclosure.

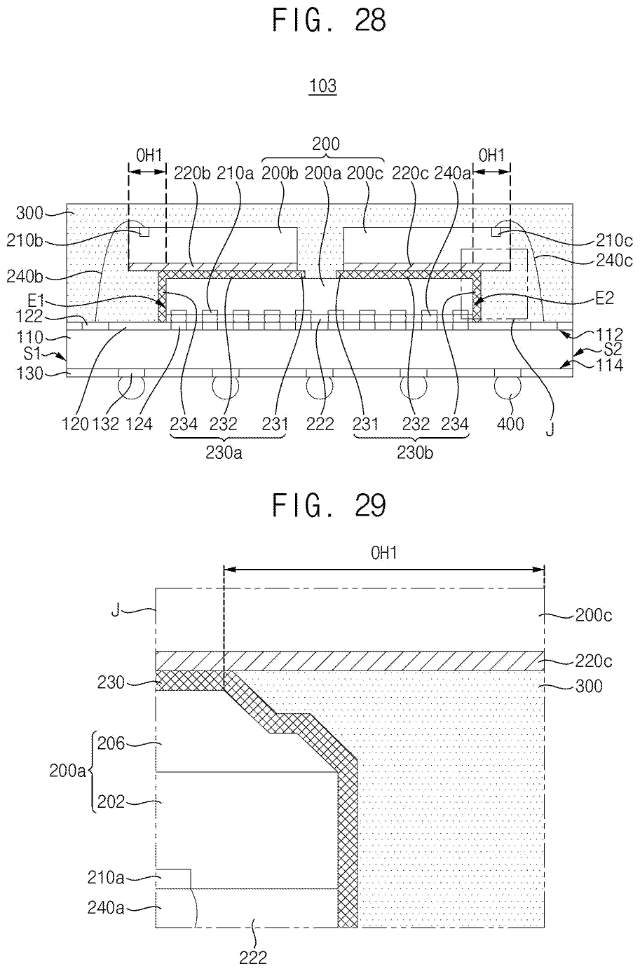

FIG. 28 is a cross-sectional view illustrating a semiconductor package in accordance with an embodiment of the present disclosure.

FIG. 29 is an enlarged cross-sectional view illustrating portion ‘J’ of FIG. 28 in accordance with an embodiment of the present disclosure.

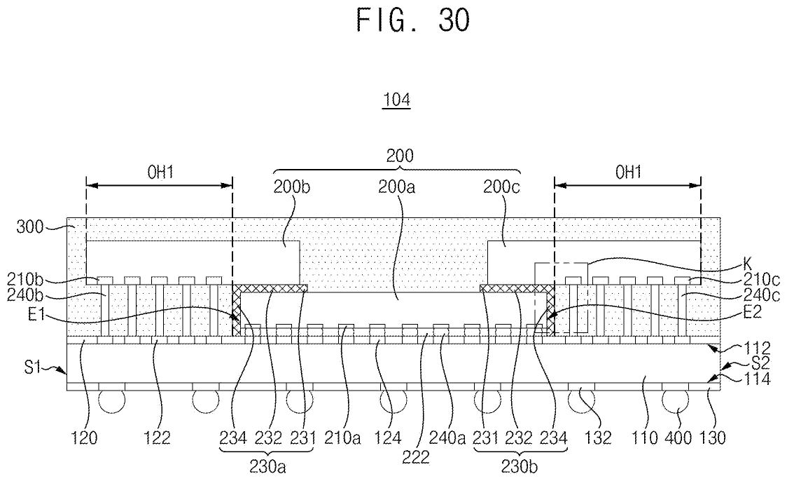

FIG. 30 is a cross-sectional view illustrating a semiconductor package in accordance with an embodiment of the present disclosure.

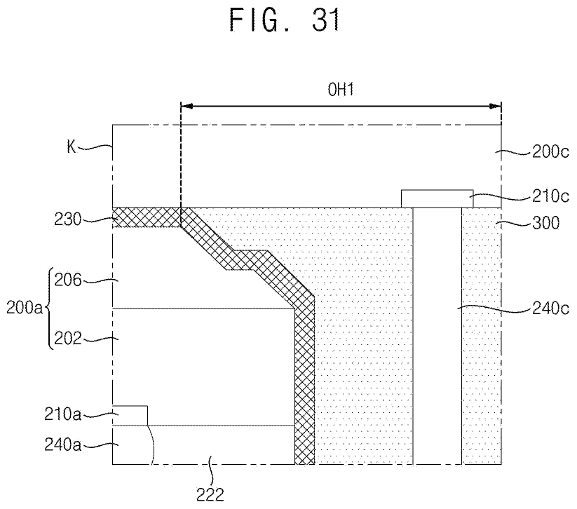

FIG. 31 is an enlarged cross-sectional view illustrating portion ‘K’ of FIG. 31 in accordance with an embodiment of the present disclosure.

### DETAILED DESCRIPTION OF EMBODIMENTS

Hereinafter, embodiments will be explained in detail with reference to the accompanying drawings.

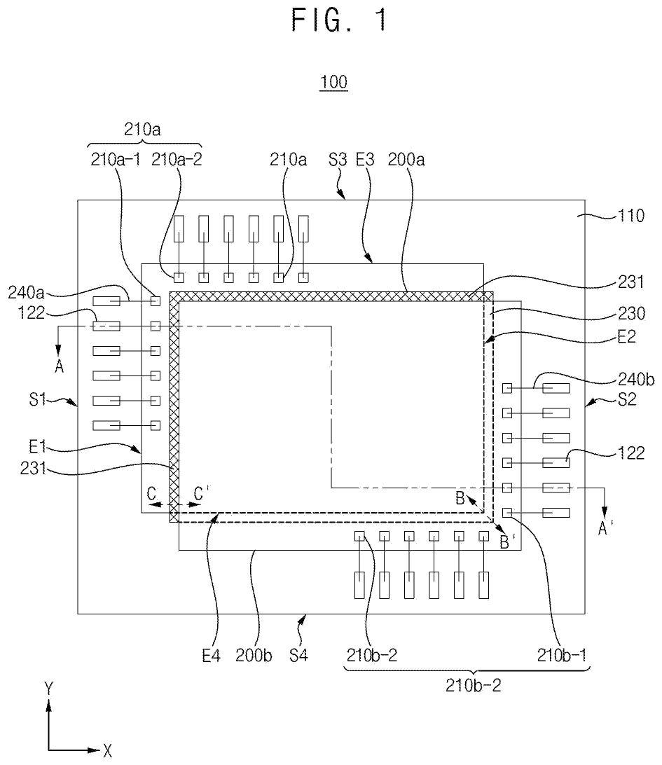

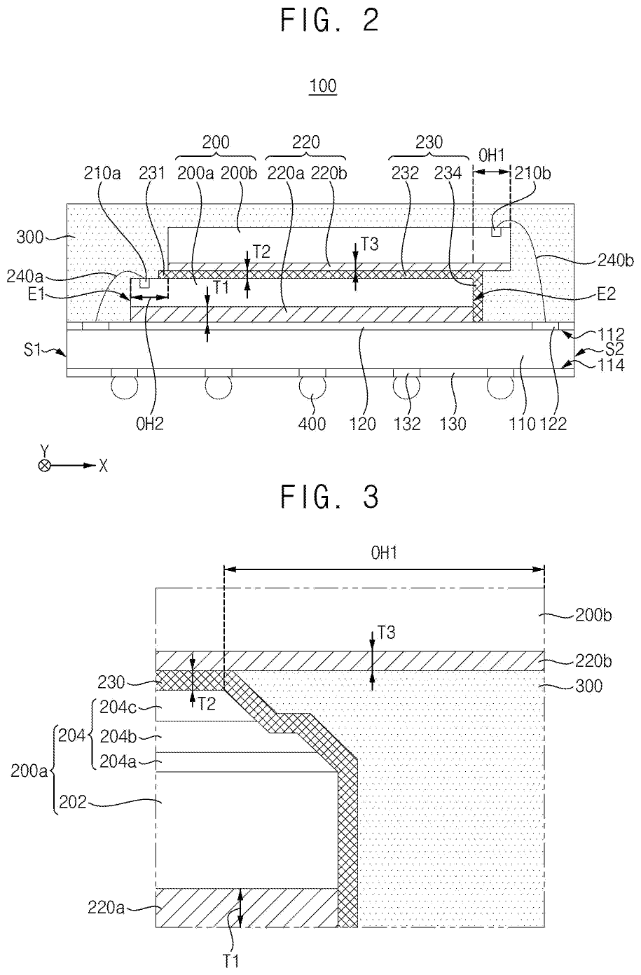

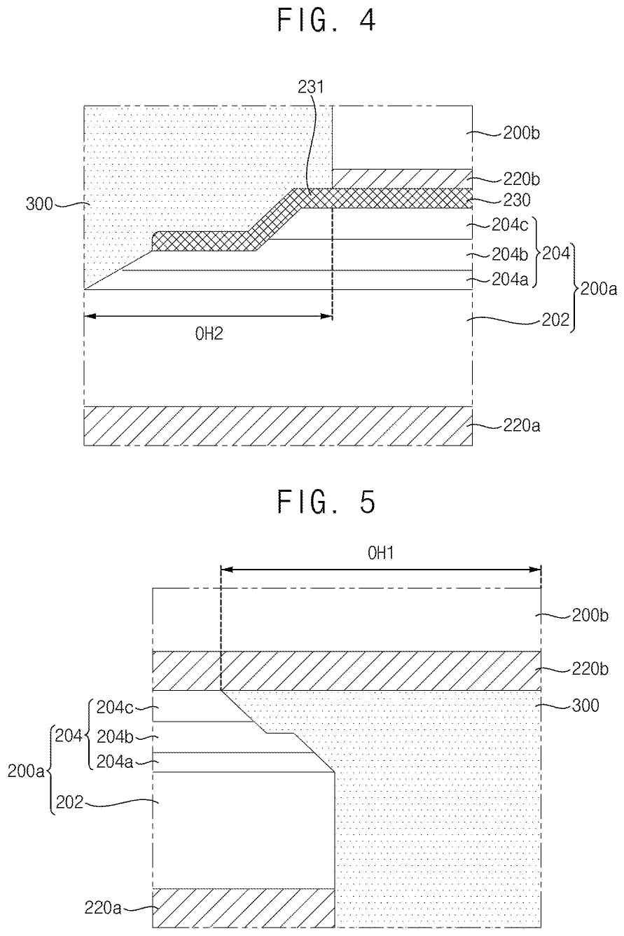

FIG. 1 is a plan view illustrating a semiconductor package in accordance with an embodiment. FIG. 2 is a cross-sectional view taken along the line A-A′ in FIG. 1. FIG. 3 is a cross-sectional view taken along the line B-B′ in FIG. 1. FIG. 4 is a cross-sectional view taken along the line C-C′ in FIG. 1. FIG. 1 is a plan view illustrating the semiconductor package in FIG. 2, wherein a molding member is omitted.

Referring to FIGS. 1 to 4, a semiconductor package 100 may include a package substrate 110, a first semiconductor chip 200a arranged on the package substrate 110, a stress relieving adhesive layer 230 covering an upper surface and at least one side surface of the first semiconductor chip 200a, a second semiconductor chip 200b stacked on the first semiconductor chip 200a, and a molding member 300. The semiconductor package 100 may further include conductive connection members 240a and 240b that electrically connect the first semiconductor chip 200a and the second semiconductor chip 200b to the package substrate 110. In addition, the semiconductor package 100 may further include external connection members 400.

In addition, in an embodiment the semiconductor package 100 may be a multi-chip package (MCP) including the same or different types of semiconductor chips. The semiconductor package (100) may be a system in package (SIP) in which a plurality of semiconductor chips are stacked or arranged in one package to perform all or most of the functions of an electronic system.

In an embodiment, the package substrate 110 may be a substrate having an upper surface 112 and a lower surface 114 facing each other (e.g., in a vertical direction). For example, in an embodiment the package substrate 110 may include a printed circuit board (PCB), a flexible substrate, a tape substrate, etc. The printed circuit board may be a multilayer circuit board having vias and various circuits therein. The package substrate 110 may include internal wirings for electrical connection between the first semiconductor chip 200a and the second semiconductor chip 200b.

The package substrate 110 may include a first side portion S1 and a second side portion S2 extending in a direction perpendicular to the upper surface 112 and parallel to a second direction (Y direction). The first and second side portions S1, S2 face each other (e.g., in a first direction X). A third side portion S3 and a fourth side portion S4 extend in a direction parallel to the first direction (X direction) perpendicular to the second direction. The third and fourth side portions S3, S4 face each other (e.g., in the Y direction).

The package substrate 110 may include substrate pads 122 that are arranged along the first to fourth side portions S1, S2, S3, S4 of the package substrate 110. While the substrate pads 122 are shown as being spaced apart from each other at equal distances, embodiments of the present disclosure are not necessarily limited thereto. The substrate pads 122 may be respectively connected to the wirings. The wirings may extend from the upper surface 112 of the package substrate 110 or inside thereof. For example, at least a portion of the wiring may be used as a landing pad for the substrate pad.

Although some substrate pads are illustrated in the figures, the number, shape, and arrangement of the substrate pads are provided as examples, and it will be understood that embodiments of the present disclosure are not necessarily limited thereto. Since the wirings including the substrate pads are widely known in the art to which embodiments of the present disclosure pertain, illustration and description thereof will be omitted.

A first insulating layer 120 may be disposed on the upper surface 112 of the package substrate 110 and may expose the substrate pads 122. In an embodiment, the first insulating layer 120 may cover the entire upper surface 112 of the package substrate 110 except for the substrate pads 122. For example, in an embodiment the first insulating layer may include a solder resist.

In an embodiment, the first semiconductor chip 200a may be attached on the package substrate 110 using a first adhesive film 220a. The first semiconductor chip 200a may be attached on the package substrate 110 using the first adhesive film 220a such as a die attach film (DAF) by a die attach process. For example, in an embodiment a thickness of the first semiconductor chip 200a may be within a range of about 40 μm to about 110 μm. A thickness T1 of the first adhesive film 220a may be within a range of about 10 μm to about 60 μm.

The first semiconductor chip 200a may be arranged such that a backside surface opposite to a front surface on which first chip pads 210a are disposed, that is, an inactive surface, faces the package substrate 110. In an embodiment, when viewed from a plan view, the first semiconductor chip 200a may have a rectangular shape having four sides.

In an embodiment, the first semiconductor chip 200a may include first and second side surfaces E1 and E2 extending in a direction parallel to the second direction (Y direction) and facing each other (e.g., in the X direction), and third and fourth side surface E3 and E4 extending in a direction parallel to the first direction (X direction) perpendicular to the second direction and facing each other (e.g., in the Y direction). In an embodiment, the first side surface E1 of the first semiconductor chip 200a may be arranged adjacent to the first side portion S1 of the package substrate 110, and the second side surface E2 of the first semiconductor chip 200a may be arranged adjacent to the second side portion S2 of the package substrate 110.

The first chip pads 210a of the first semiconductor chip 200a may include first pads 210a-1 arranged in the Y direction along the first side surface E1 and second pads 210a-2 arranged in the X direction along the second side surface E2.

In an embodiment, the first semiconductor chip may be a logic chip including a logic circuit. For example, the logic chip may be a controller that controls a memory chip. In an embodiment, the first semiconductor chip may be a processor ship such as ASIC, an application processor (AP), etc. serving as a host such as a CPU, GPU, or SOC.

Alternatively, the first semiconductor chip may include a memory chip including a memory circuit. For example, the first semiconductor chip may include volatile memory devices such as DRAM devices, SRAM devices, etc. or non-volatile memory devices such as flash memory devices, PRAM devices, MRAM devices, ReRAM devices, etc. However, embodiments of the present disclosure are not necessarily limited thereto.

In an embodiment, the first semiconductor chip 200a may be mounted on the package substrate 110 by a wire bonding method. The first chip pads 210a of the first semiconductor chip 200a may be electrically connected to the substrate pads 122 on the upper surface 112 of the package substrate 110 by the conductive connection members such as bonding wires 240a.

In an embodiment, a stress relieving adhesive layer 230 may be attached to the upper surface, the second side surface E2, and the fourth side surface E4 of the first semiconductor chip 200a. In an embodiment, the stress relieving adhesive layer 230 may include a first adhesive portion 232 that covers the upper surface of the first semiconductor chip 200a and exposes the first chip pads 210a, and a second adhesive portion 234 that extends vertically downward from the first adhesive portion 232 to the first insulating layer 120 to cover the second side surface E2 and the fourth side surface E4 of the first semiconductor chip 200a.

For example, the stress relieving adhesive layer 230 may have a thickness T2 less than the thickness T1 of the first adhesive film 220a. In an embodiment, the thickness T2 of the stress relieving adhesive layer 230 may be within a range of about 10 μm to about 30 μm. The stress relieving adhesive layer 230 may include a material having the same or similar hygroscopic strain as the first adhesive film 220a. For example, the stress relieving adhesive layer 230 may include the same material as the first adhesive film 220a. Alternatively, the stress relieving adhesive layer 230 may include the same material as the molding member 300. In an embodiment, the stress relieving adhesive layer 230 may include a die attach film (DAF), a thermosetting resin, or the like.

The stress relieving adhesive layer 230 may be formed on the entire surface of the first semiconductor chip 200a or may be formed locally on portions of surfaces where different materials meet. The formation position of the stress relieving adhesive layer 230 may be determined in consideration of a position where different materials meet, a stacked structure of semiconductor chips, etc.

In an embodiment, the second semiconductor chip 200b may be attached on the stress relieving adhesive layer 230 on the first semiconductor chip 200a by a second adhesive film 220b. The second semiconductor chip 200b may be attached on the first adhesive portion 232 of the stress relieving adhesive layer 230 using the second adhesive film 220b such as a die attach film (DAF) by a die attach process. For example, in an embodiment a thickness T3 of the second adhesive film 220b may be within a range of about 10 μm to about 40 μm.

The second semiconductor chip 200b may be arranged such that a backside surface, such as an inactive surface, opposite to a front surface on which second chip pads 210b are formed faces the first semiconductor chip 200a. In an embodiment, the second semiconductor chip 200b may have a rectangular shape having four sides when viewed from a plan view (e.g., in a plane defined in the X and Y directions). In an embodiment, the second semiconductor chip 200b may have the same or similar shape as the first semiconductor chip 200a. In an embodiment, the second semiconductor chip may include the same type of memory chip as the first semiconductor chip.

The second semiconductor chip 200b may be offset-aligned in a horizontal direction on the first semiconductor chip 200a. For example, in an embodiment the second semiconductor chip 200b may be offset-aligned in the second direction (X direction) to expose the first pads 210a-1 in the Y direction. In an embodiment, the second semiconductor chip 200b may be offset-aligned in the first direction (Y direction) to expose the second pads 210a-2 in the X direction.

Accordingly, the second semiconductor chip 200b may have a first overhang region OH1 that protrudes from the second side surface E2 or the fourth side surface E4 of the first semiconductor chip 200a, such as a protruding portion. In addition, the first semiconductor chip 200a may have a second overhang region OH2 that protrudes from the second semiconductor chip 200b, such as a protruding portion. The second semiconductor chip 200b may be offset-aligned in the horizontal direction on the first adhesive portion 232 to expose a peripheral portion 231 of the first adhesive portion 232 of the stress relieving adhesive layer 230.

In an embodiment, the second chip pads 210b of the second semiconductor chip 200b may include first pads 210b-1 in the Y direction and second pads 210b-2 in the X direction that are arranged on the upper surface of the first overhang region.

However, the number, the structure and the arrangement, etc., of the first and second semiconductor chips are not necessarily limited thereto. In addition, although at least some first and second chip pads are illustrated in the figure, the structure, the shape, and the arrangement of the first and second chip pads are not necessarily limited thereto.

The second semiconductor chip may include a memory chip including a memory circuit. For example, in an embodiment the second semiconductor chip may include volatile memory devices such as SRAM devices and DRAM devices, and nonvolatile memory devices such as flash memory devices, PRAM devices, MRAM devices, and RRAM devices.

In an embodiment, the second semiconductor chip 200b may be mounted on the package substrate 110 by a wire bonding method. The second chip pads 210b of the first semiconductor chip 200a may be electrically connected to the substrate pads 122 on the upper surface 112 of the package substrate 110 by the conductive connection members such as bonding wires 240b.

The number, the structure and the arrangement, etc., of the first and second semiconductor chips are not necessarily limited thereto. In addition, although at least some first and second chip pads are illustrated in the figure, the structure, the shape, and the arrangement of the first and second chip pads are not necessarily limited thereto.

In an embodiment, the molding member 300 may cover the first and second semiconductor chips 200 and the bonding wires 240a and 240b on the upper surface 112 of the package substrate 110. In an embodiment, the molding member may include a thermosetting resin, for example, an epoxy mold composite (EMC). However, embodiments of the present disclosure are not necessarily limited thereto.

As illustrated in FIGS. 3 and 4, in embodiments, the first semiconductor chip 200a may include a substrate 202 having circuit elements disposed on an upper surface thereof and a front insulating layer 204 disposed on the upper surface of the substrate 202 to protect the circuit elements. For example, the front insulating layer 204 may include first, second and third upper insulating layers 204a, 204b and 204c sequentially stacked on one another (e.g., in a vertical direction). The first upper insulating layer 204a may be a passivation layer that covers an upper wiring layer having a low dielectric constant (low-K). The second upper insulating layer 204b may be a silicon oxide layer including TEOS. The third upper insulating layer 204c may be a protective layer such as photosensitive polyimide (PSPI).

In an embodiment in which the first semiconductor chip 200a is individually separated by cutting a wafer by a dicing process, an edge portion between the upper surface of the first semiconductor chip 200a and the second side surface E2 (or the fourth side surface E4) may be chipped, and thus, an upper edge portion of the front insulating layer 204 may have an inclined surface exposed to the outside.

As illustrated in FIG. 3, the stress relieving adhesive layer 230 may be formed to cover the inclined surface of the upper edge portion of the first semiconductor chip 200a under the first overhang region OH1 of the second semiconductor chip 200b. The upper edge portion of the first semiconductor chip 200a may not be in direct contact with the EMC of the molding member 300 and may be spaced apart from the molding member 300 by the stress relieving adhesive layer 230. Since the inclined surface of the upper edge portion of the first semiconductor chip 200a under the first overhang region OH1 is covered by DAF of the stress relieving adhesive layer 230 that has relatively large amount of hygroscopic expansion than EMC, the pressure of the stress relieving adhesive layer 230 pressing the upper edge portion of the front insulating layer 204 downward may be increased to thereby prevent an edge peeling-off due to a difference in hygroscopic expansion at the portion where different materials meet.

As illustrated in FIG. 4, the peripheral portion 231 of the stress relieving adhesive layer 230 may be formed to cover an inclined surface of an upper edge portion of the second overhang region OH2 of the first semiconductor chip 200a adjacent to the second adhesive film 220b. The stress relieving adhesive layer 230 that includes DAF with a relatively large amount of hygroscopic expansion as compared to EMC of the molding member 300 may cover the inclined surface of the upper edge portion, and thus, the stress relieving adhesive layer 230 may relieve stress concentration due to EMC expansion and may exert a force in the opposite direction to tensile stress that causes peeling at the interface of the front insulating layer 204 on the DAF having relatively large hygroscopic strain, thereby preventing stress overload.

In an embodiment, external connection pads 132 for providing electrical signals may be disposed on the lower surface 114 of the package substrate 110. The external connection pads 132 may be exposed by a second insulating layer 130. In an embodiment, the second insulating layer 130 may include a silicon oxide layer, a silicon nitride layer, or a silicon oxynitride layer. However, embodiments of the present disclosure are not necessarily limited thereto The external connection member 400 for electrical connection with an external device may be disposed on the external connection pad 132 of the package substrate 110. For example, in an embodiment the external connection member 400 may be a solder ball. In an embodiment, the semiconductor package 100 may be mounted on a module substrate via the solder balls to form a memory module.

As mentioned above, the semiconductor package 100 may include the first semiconductor chip 200a disposed on the package substrate 110 and having the first chip pads 210a arranged on the upper surface of the first semiconductor along the first side surface E1, the stress relieving adhesive layer 230 that covers the upper surface of the first semiconductor chip 200a except for the first chip pads 210a and extends vertically downward from the upper surface to cover the second side surface E2 facing the first side surface E1, the second semiconductor chip 200b attached on the stress relieving adhesive layer 230 on the first semiconductor chip 200a by the adhesive film 220b, and offset-aligned in the horizontal direction from the first side surface E1 toward the second side surface E2 to expose the first chip pads 210a, and the molding member covering the first and second semiconductor chips 200a and 200b on the package substrate 110.

The stress relieving adhesive layer 230 may cover the second side surface E2 of the first semiconductor chip 200a under the first overhang region OH1 of the second semiconductor chip 200b, so that the upper edge portion of the second side surface E2 of the first semiconductor chip 200a is not in direct contact with the EMC material of the molding member 300. The pressure of the stress relieving adhesive layer 230 that presses the upper edge portion of the second side surface E2 of the first semiconductor chip 200a downward may increase so that the peeling-off due to the difference in amount of hygroscopic expansion at the portion where different materials meet may be prevented.

Further, the stress relieving adhesive layer 230 may cover the upper edge portion of the second overhang region OH2 of the first semiconductor chip 200a adjacent to the second adhesive film 220b, so that the upper edge portion of the first semiconductor chip 200a is not in direct contact with the EMC material of the molding member 300.

Accordingly, the stress relieving adhesive layer 230 may be arranged to cover the edge portion of the semiconductor chip adjacent to the overhang region to prevent stress overload in the triple point region where three different materials meet, thereby increasing the mechanical reliability of the semiconductor package 100.

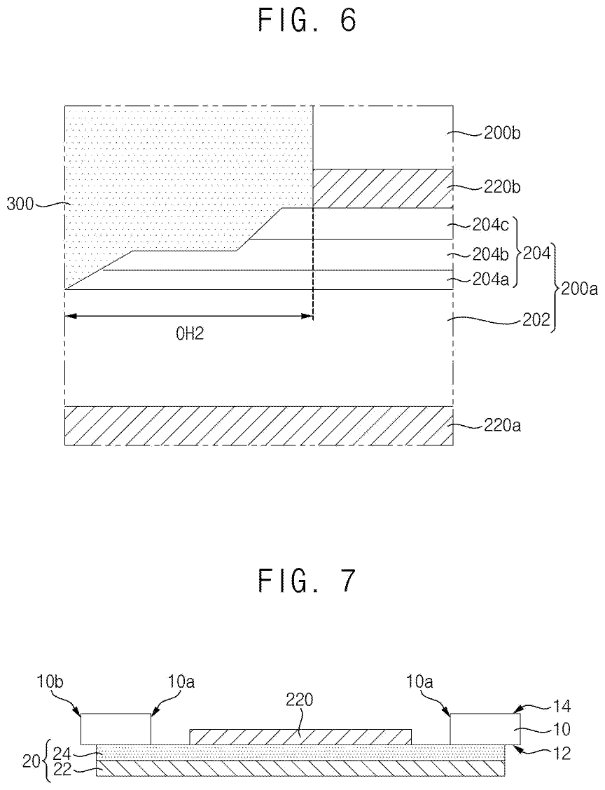

FIG. 5 is a cross-sectional view taken along the line B-B′ in FIG. 1 in accordance with a comparative embodiment. FIG. 6 is a cross-sectional view taken along the line C-C′ in FIG. 1 in accordance with a comparative embodiment.

Referring to FIG. 5, according to a comparative embodiment, a triple point where DAF of the second adhesive film 220b, EMC of the molding member 300, and PSPI of the front insulating layer 204 meet may occur at the upper edge portion of the first semiconductor chip 200a under the first overhang region OH1 of the second semiconductor chip 200b, and the peeling-off may occur due to a difference in hygroscopic strain at the triple point. Hygroscopic strain of DAF is 0.2CHS, hygroscopic strain of PSPI is 0.089CHS, and hygroscopic strain of EMC is 0.05 to 0.011CHS. Here, CHS (% strain/% wt) represents the coefficient of hygroscopic swelling.

Referring to FIG. 6, according to a comparative embodiment, a triple point where DAF of the second adhesive film 220b, EMC of the molding member 300, and PSPI of the front insulating layer 204 meet may occur at the upper edge portion of the first semiconductor chip 200a on the second overhang region OH2 of the first semiconductor chip 200a, and the peeling-off may occur due to a difference in hygroscopic strain at the triple point.

Hereinafter, a method of manufacturing the semiconductor package in FIG. 1 will be explained.

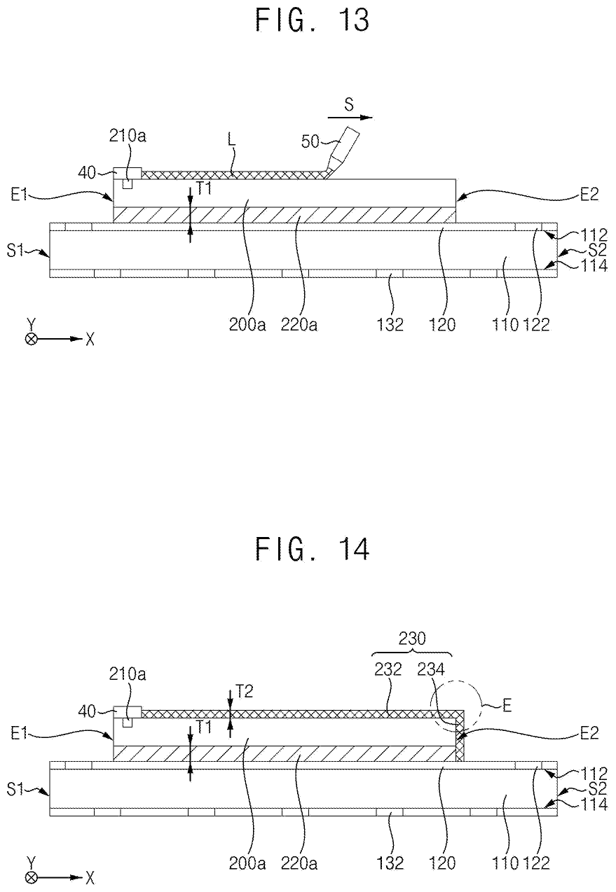

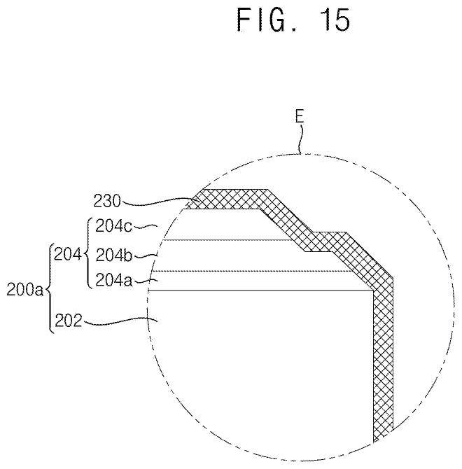

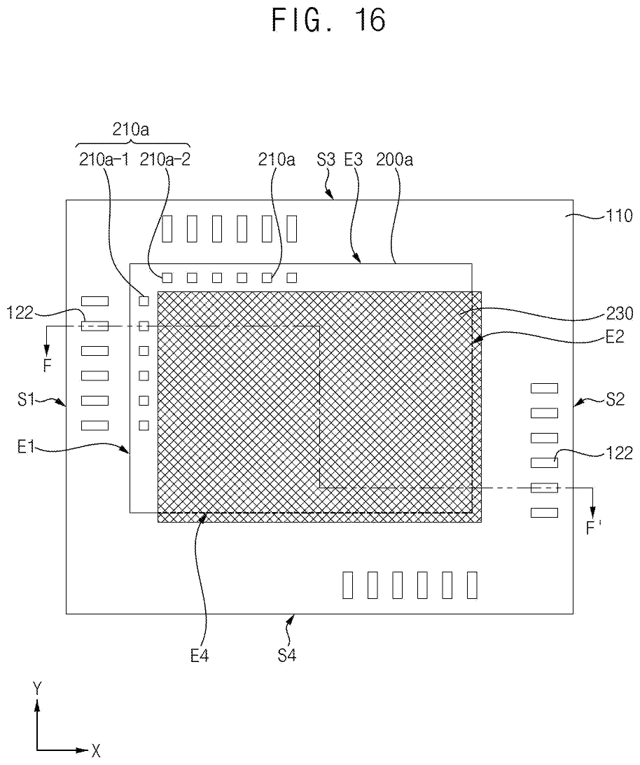

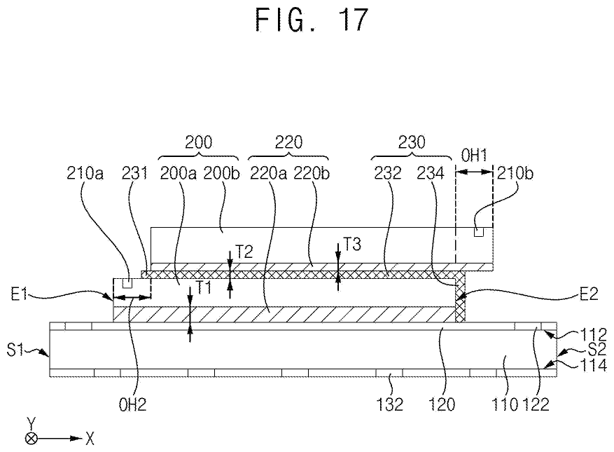

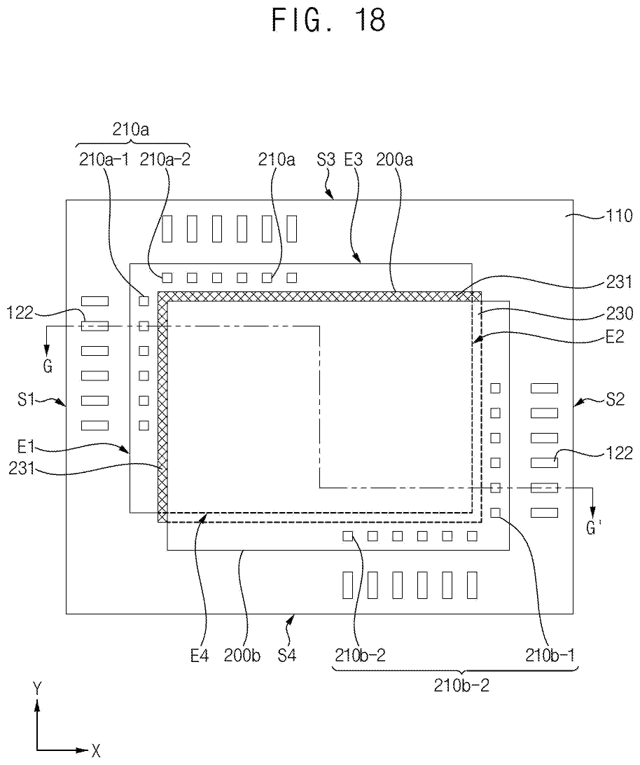

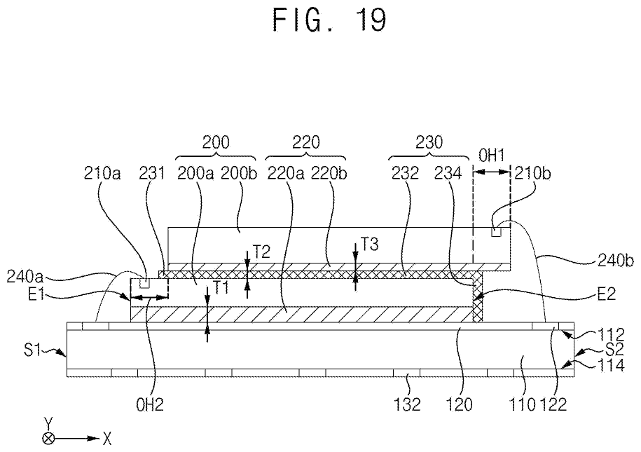

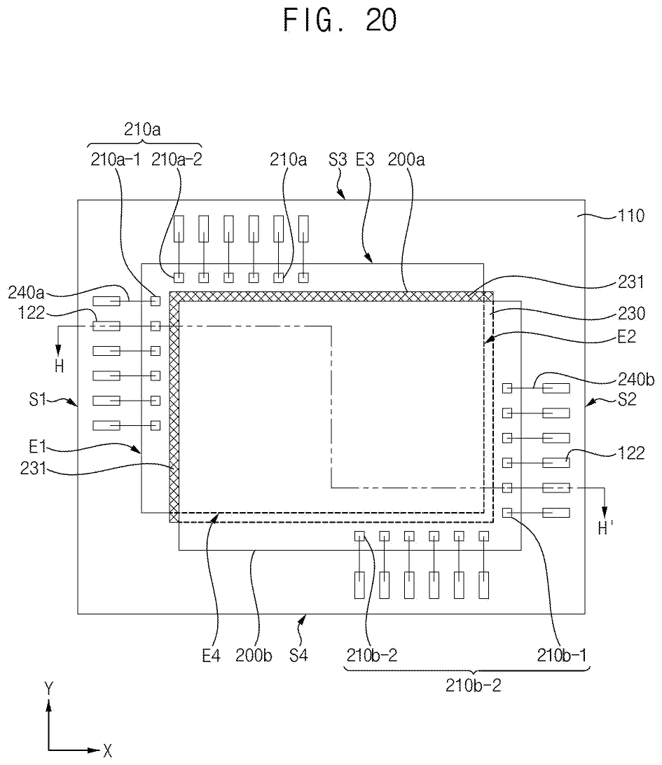

FIGS. 7 to 21 are views illustrating a method of manufacturing a semiconductor package in accordance with embodiments. FIGS. 7 to 10 are cross-sectional views illustrating processes of separating individual semiconductor chips from a wafer. FIGS. 11 to 21 are views illustrating processes of mounting individual semiconductor chips on a package substrate. FIG. 11 is a cross-sectional view taken along the line D-D′ in FIG. 12. FIG. 15 is an enlarged cross-sectional view illustrating portion ‘E’ in FIG. 14. FIG. 14 is a cross-sectional view taken along the line F-F′ in FIG. 16. FIG. 17 is a cross-sectional view taken along the line G-G′ in FIG. 18. FIG. 19 is a cross-sectional view taken along the line H-H′ in FIG. 20.

Referring to FIGS. 7 to 10, a wafer W may be cut by a dicing process to form individual semiconductor chips 200.

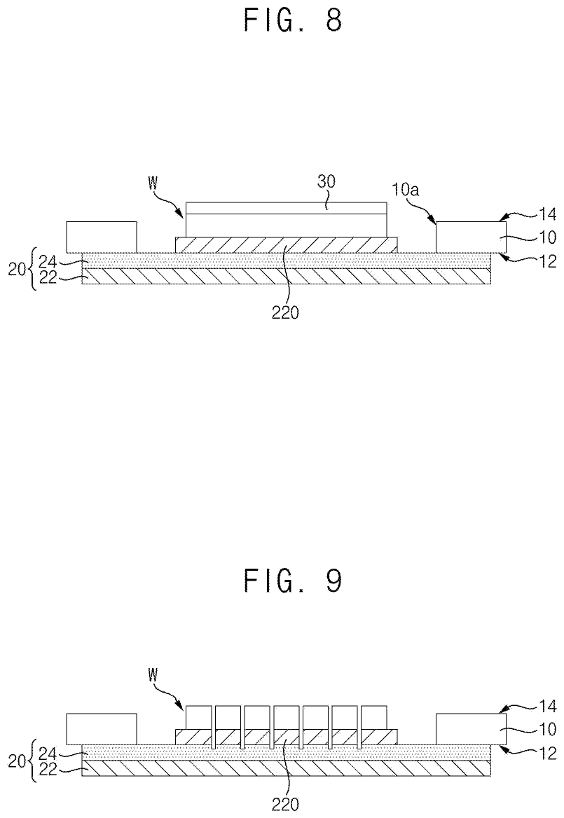

As illustrated in FIGS. 7 and 8, in an embodiment a dicing tape 20 may be attached to a lower surface 12 of a ring frame 10, and the semiconductor wafer W having a plurality of semiconductor chips formed therein may be attached on an adhesive film 220.

In embodiments, the dicing tape 20 may be attached to the ring frame 10 by an adhesive force of an adhesive layer 24 of the dicing tape 20. The ring frame 10 may have an inner surface 10a that defines a receiving space therein and an outer surface 10b opposite to the inner surface 10a in a radial direction. The adhesive film 220 on the adhesive layer 24 of the dicing tape 20 may be arranged in the receiving space of the ring frame 10. The adhesive film 220 may be spaced apart from the inner surface 10a of the ring frame 10. In an embodiment, the adhesive film 220 may include a die attach film (DAF) as an organic adhesive.

After attaching a protective tape 30 for protecting circuit elements on a first surface (e.g., an active surface) of the silicon wafer W on which a fabrication process called a Front End of Line (FEOL) process for manufacturing semiconductor devices has been performed, a second surface (e.g., a backside surface) opposite to the first surface of the wafer W may be partially removed by a grinding process such that the wafer W has a desired thickness. In an embodiment, the wafer may be polished to have a thickness in a range of about 40 μm to about 120 μm. However, embodiments of the present disclosure are not necessarily limited thereto. After performing the grinding process, the second surface of the wafer W may be attached on the adhesive film 220. After performing the grinding process, the protective tape 30 may be removed from the wafer W.

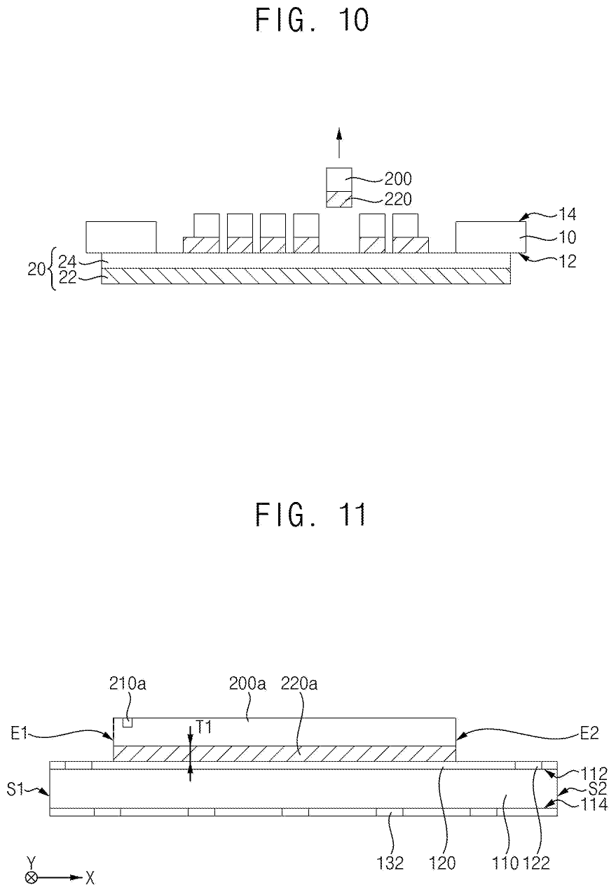

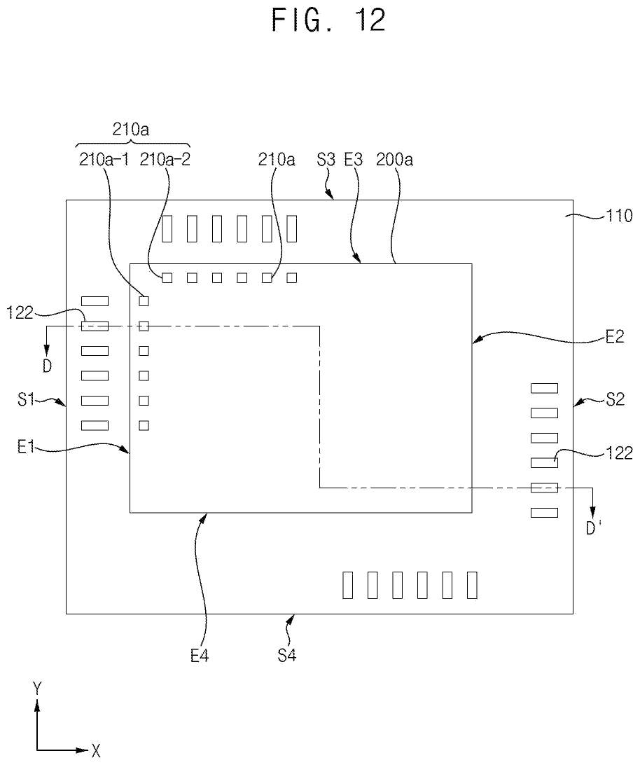

As illustrated in FIG. 9, a dicing process may be performed to form a preliminary cutting line for dividing the wafer W into a plurality of semiconductor chips. For example, in an embodiment the dicing process may be performed by irradiating a laser beam along a scribe lane region or using a blade. However, embodiments of the present disclosure are not necessarily limited thereto.

As illustrated in FIG. 10, the wafer W may be divided into a plurality of individual semiconductor chips 200 by expanding the dicing tape 20. In an embodiment, a tape expanding apparatus may expand the dicing tape in a radial direction, allowing the separated semiconductor chips 200 on the dicing tape to be radially spaced apart from each other.

As will be described below, in an embodiment the semiconductor chip 200 to which the adhesive film 220 is attached may be attached on the package substrate or another semiconductor chip by a pick-up process to form the semiconductor package.

Referring to FIGS. 11 and 12, a first semiconductor chip 200a may be arranged on a package substrate 110. The semiconductor chip 200 in FIG. 10 may be provided as the first semiconductor chip.

In an embodiment, the package substrate 110 may be a substrate having an upper surface 112 and a lower surface 114 facing each other (e.g., in a vertical direction). For example, in an embodiment the package substrate 110 may be a printed circuit board (PCB). The printed circuit board may be a multilayer circuit board having vias and various circuits therein. The package substrate 110 may include internal wirings for electrical connection between a first semiconductor chip and a second semiconductor chip, which will be described below.

The package substrate 110 may include a first side portion S1 and a second side portion S2 extending in a direction perpendicular to the upper surface 112 and parallel to a second direction (e.g., the Y direction) and facing each other, (e.g., in the X direction) and a third side portion S3 and a fourth side portion S4 extending in a direction parallel to a first direction (e.g., the X direction) perpendicular to the second direction and facing each other (e.g., in the Y direction).

The package substrate 110 may include substrate pads 122 that are arranged along the side portions S1, S2, S3, S4 of the package substrate 110. The substrate pads 122 may be respectively connected to the wirings. The wirings may extend from the upper surface 112 of the package substrate 110 or inside thereof. For example, in an embodiment at least a portion of the wiring may be used as a landing pad for the substrate pad.

Although only a few substrate pads are illustrated in the figure, the number, shape, and arrangement of the substrate pads are provided as examples, and embodiments of the present disclosure are not necessarily limited thereto. Since the wirings including the substrate pads are widely known in the art to which the present disclosure pertains, illustration and description thereof may be omitted.

A first insulating layer 120 may be formed on the upper surface 112 of the package substrate 110 to expose the substrate pads 122. For example, in an embodiment the first insulating layer 120 may cover the entire upper surface 112 of the package substrate 110 except for the substrate pads 122. In an embodiment, the first insulating layer may include a solder resist.

In an embodiment, the first semiconductor chip 200a may be attached on the package substrate 110 using a first adhesive film 220a. In an embodiment, the first semiconductor chip 200a may be attached on the package substrate 110 using the first adhesive film 220a, such as a die attach film (DAF) by a die attach process. For example, a thickness of the first semiconductor chip 200a may be within a range of about 40 μm to about 110 μm. A thickness T1 of the first adhesive film 220a may be within a range of about 10 μm to about 60 μm.

The first semiconductor chip 200a may be arranged such that a backside surface opposite a front surface on which first chip pads are formed, such as an inactive surface, faces the package substrate 110. In an embodiment, when viewed from a plan view (e.g., in a plane in the X and Y directions), the first semiconductor chip 200a may have a rectangular shape having four sides.

For example, the first semiconductor chip 200a may include first and second side surfaces E1 and E2 extending in a direction parallel to the second direction (e.g., the Y direction) and facing each other (e.g., in the X direction), and third and fourth side surface E3 and E4 extending in a direction parallel to the first direction (e.g., the X direction) perpendicular to the second direction and facing each other (e.g., in the Y direction). The first side surface E1 of the first semiconductor chip 200a may be arranged adjacent to the first side portion S1 of the package substrate 110, and the second side surface E2 of the first semiconductor chip 200a may be arranged adjacent to the second side portion S2 of the package substrate 110.

In an embodiment, the first chip pads 210a of the first semiconductor chip 200a may include first pads 210a-1 arranged in the Y direction along the first side surface E1 and second pads 210a-2 arranged in the X direction along the second side surface E2.

In an embodiment, the first semiconductor chip 200a may be a logic chip including a logic circuit. The logic chip may be a controller that controls memory chips. The first semiconductor chip may be a processor chip such as ASIC, an application processor (AP), etc. serving as a host such as a CPU, GPU, or SOC.

Alternatively, in an embodiment the first semiconductor chip 200a may include a memory chip including a memory circuit. For example, the first semiconductor chip 200a may include volatile memory devices such as DRAM devices, SRAM devices, etc. or non-volatile memory devices such as flash memory devices, PRAM devices, MRAM devices, ReRAM devices, etc.

Referring to FIGS. 13 to 16, a stress relieving adhesive layer 230 may be coated on an upper surface, the second side surface E2 and the fourth side surface E4 of the first semiconductor chip 200a.

As illustrated in FIG. 13, in an embodiment a mask 40 may be formed to cover the first chip pads 210a and to extend in the second direction (e.g., the Y direction) and the first direction (e.g., the X direction) along the first side surface E1 and a third side surface E3, and a liquid adhesive L may be dispensed onto the surface of the first semiconductor chip 200a exposed by the mask 40 while moving a dispenser nozzle 50 in a scanning direction S. The liquid adhesive L may be cured to form the stress relieving adhesive layer 230. Alternatively, the stress relieving adhesive layer 230 may be formed by a printing process.

In an embodiment, the stress relieving adhesive layer 230 may include a first adhesive portion 232 that covers the upper surface of the first semiconductor chip 200a and exposes the first chip pads 210a and a second adhesive portion 234 that extends vertically downward from the first adhesive portion 232 to the first insulating layer 120 to cover the second side surface E2 and a fourth side surface E4 of the first semiconductor chip 200a.

For example, in an embodiment the stress relieving adhesive layer 230 may have a thickness T2 that is less than the thickness T1 of the first adhesive film 220a. In an embodiment, the thickness T2 of the stress relieving adhesive layer 230 may be within a range of about 10 μm to about 30 μm. The stress relieving adhesive layer 230 may include a material having the same or similar hygroscopic strain as the first adhesive film 220a. Alternatively, the stress relieving adhesive layer 230 may include the same material as a molding member described below. In an embodiment, the stress relieving adhesive layer 230 may include a die attach film (DAF), a thermosetting resin, or the like.

As illustrated in FIG. 15, the first semiconductor chip 200a may include a substrate 202 having circuit elements disposed on an upper surface thereof and a front insulating layer 204 disposed on the upper surface of the substrate 202 to protect the circuit elements. For example, in an embodiment the front insulating layer 204 may include first, second and third upper insulating layers 204a, 204b and 204c sequentially stacked on one another. In an embodiment, the first upper insulating layer 204a may be a passivation layer that covers an upper wiring layer having a low dielectric constant (low-K). The second upper insulating layer 204b may be a silicon oxide layer including TEOS. The third upper insulating layer 204c may be a protective layer such as photosensitive polyimide (PSPI).

Through the dicing process, an edge portion between the upper surface of the first semiconductor chip 200a and the second side surface E2 (or the fourth side surface E4) may be chipped, and thus, an upper edge portion of the front insulating layer 204 may have an inclined surface exposed to the outside. The stress relieving adhesive layer 230 may be formed to cover the inclined surface of the upper edge portion of the first semiconductor chip 200a, and accordingly, the occurrence of a triple point where three different materials meet through the inclined surface of the first semiconductor chip 200a may be prevented to remove or reduce stress concentration due to a difference in hygroscopic strain, to thereby prevent peel-off defects at the upper edge portion.

Referring to FIGS. 17 and 18, the mask 40 may be removed from the upper surface of the first semiconductor chip 200a, and a second semiconductor chip 200b may be attached on the stress relieving adhesive layer 230 on the first semiconductor chip 200a using a second adhesive film 220b. In an embodiment, the second semiconductor chip 200b may be attached to the first adhesive portion 232 of the stress relieving adhesive layer 230 using the second adhesive film 220b such as a die attach film (DAF) by a die attach process. For example, in an embodiment a thickness T3 of the second adhesive film 220b may be within a range of about 10 μm to about 40 μm.

The second semiconductor chip 200b may be arranged such that a backside surface, such as an inactive surface, opposite to a front surface on which second chip pads 210b are formed faces the first semiconductor chip 200a (e.g., in a vertical direction). In an embodiment, the second semiconductor chip 200b may have a rectangular shape having four sides when viewed in a plan view (e.g., in a plane defined in the X and Y directions). In an embodiment, the second semiconductor chip 200b may have the same shape as the first semiconductor chip 200a. In an embodiment, the second semiconductor chip may include the same type of memory chip as the first semiconductor chip.

The second semiconductor chip 200b may be offset-aligned in a horizontal direction on the first semiconductor chip 200a. In an embodiment, the second semiconductor chip 200b may be offset-aligned in the second direction (e.g., the X direction) to expose the first pads 210a-1 in the Y direction. The second semiconductor chip 200b may be offset-aligned in the first direction (e.g., the Y direction) to expose the second pads 210a-2 (e.g., additional first pads) in the X direction.

Accordingly, the second semiconductor chip 200b may have a first overhang region OH1 that protrudes from the second side surface E2 or the fourth side surface E4 of the first semiconductor chip 200a, such as a protruding portion. In addition, the first semiconductor chip 200a may have a second overhang region OH2 that protrudes from the second semiconductor chip 200b, such as a protruding portion. The second semiconductor chip 200b may be offset-aligned on the first adhesive portion 232 in the horizontal direction to expose a peripheral portion 231 of the first adhesive portion 232 of the stress relieving adhesive layer 230.

The second chip pads 210b of the second semiconductor chip 200b may include first pads 210b-1 in the Y direction and second pads 210b-2 in the X direction arranged on the upper surface of the first overhang region.

The number, the structure and the arrangement of the first and second semiconductor chips are not necessarily limited to that shown in FIG. 18. In addition, at least some first and second chip pads are illustrated in the figure, the structure, the shape, and the arrangement of the first and second chip pads are not necessarily limited thereto.

In an embodiment, a curing process may be performed to cure the first and second adhesive films 220a and 220b and the stress relieving adhesive layer 230. For example, after loading the package substrate on which the first and second semiconductor chips are attached into a pressure chamber, the curing process may be performed under an increased pressure in the pressure chamber.

Referring to FIGS. 19 and 20, the first and second semiconductor chips 200a and 200b may be electrically connected to the package substrate 110 by conductive connection members 240a and 240b.

In an embodiment, a wire bonding process may be performed to connect the first and second chip pads 210a and 210b of the first and second semiconductor chips 200a and 200b to the substrate pads 122 on the upper surface 112 of the package substrate 110.

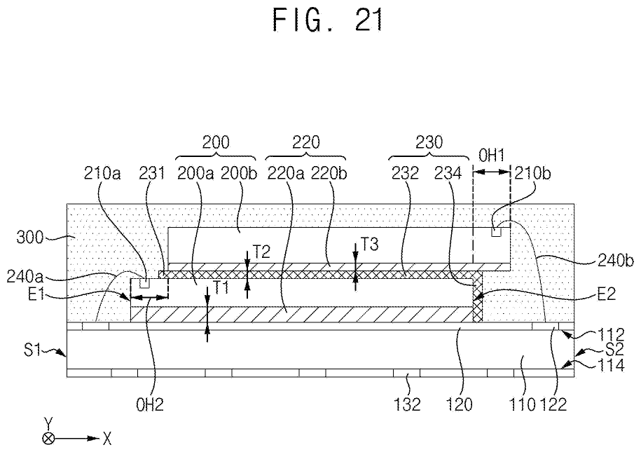

Referring to FIG. 21, a molding member 300 may be disposed on the upper surface 112 of the package substrate 110 to cover the first and second semiconductor chips 200a and 200b and bonding wires 240a and 240b. In an embodiment, the molding member may include a thermosetting resin, for example, an epoxy mold composite (EMC). However, embodiments of the present disclosure are not necessarily limited thereto.

Then, external connection members may be formed on external connection pads 132 on the lower surface 114 of the package substrate 110 to complete the semiconductor package 100 in FIG. 1.

For example, the external connection members may include solder balls. In an embodiment, the external connection members may be formed respectively on the external connection pads 132 of the lower surface 114 of the package substrate 110 by a solder ball attach process.

FIG. 22 is a cross-sectional view illustrating a semiconductor package in accordance with an embodiment. The semiconductor package is substantially the same as the semiconductor package described with reference to FIGS. 1 and 2, except for a stress relieving adhesive layer. Thus, same reference numerals will be used to refer to the same or similar elements and any further repetitive explanation concerning the above elements may be omitted for economy of description.

Referring to FIG. 22, a semiconductor package 101 may include a package substrate 110, a first semiconductor chip 200a arranged on the package substrate 110, a stress relieving adhesive layer 230 covering a surface of the first semiconductor chip 200a, a second semiconductor chip 200b attached to the stress relieving adhesive layer 230 on the first semiconductor chip 200a by an adhesive film 220b and offset-aligned in a horizontal direction, and a molding member 300 covering the first and second semiconductor chips 200a and 200b on the package substrate 110.

In an embodiment, a stress relieving adhesive layer 230 may cover an upper surface of the first semiconductor chip 200a and first to fourth side surfaces E1, E2, E3, and E4 except for bonding wires 240a connected to first chip pads 210a. The stress relieving adhesive layer 230 may include a first adhesive portion 232 covering the upper surface of the first semiconductor chip 200a and a second adhesive portion 234 extending vertically downward to the first insulating layer 120 to cover the first to fourth side surfaces E1, E2, E3, E4 of the first semiconductor chip 200a.

Since the stress relieving adhesive layer 230 covers the entire surface of the first semiconductor chip 200a except for the bonding wires 240a connected to the first chip pads, an upper edge portion of the first semiconductor chip 200a under a first overhang region OH1 of the second semiconductor chip 200b may not be in direct contact with an EMC material of the molding member 300, and an upper edge portion of a second overhang region OH2 of the first semiconductor chip 200a adjacent to the second adhesive film 220b may not be in direct contact with the EMC material of the molding member 300.

Thus, the stress relieving adhesive layer 230 may prevent stress overload in the triple point region where three different materials meet to prevent an edge peeling-off failure due to a difference in the amount of expansion at the portion where different materials meet.

Hereinafter, a method of manufacturing a semiconductor package in FIG. 22 will be described.

FIGS. 23 to 25 are cross-sectional views illustrating a method of manufacturing a semiconductor package in accordance with embodiments of the present disclosure.

Referring to FIG. 23, processes the same as or similar to processes described with reference to FIGS. 11 and 12 may be performed to arrange a first semiconductor chip 200a on a package substrate 110, and a wire bonding process may be performed to connect first chip pads 210a of a first semiconductor chip 200a to substrate pads 122 on an upper surface 112 of the package substrate 110 by bonding wires 240a.

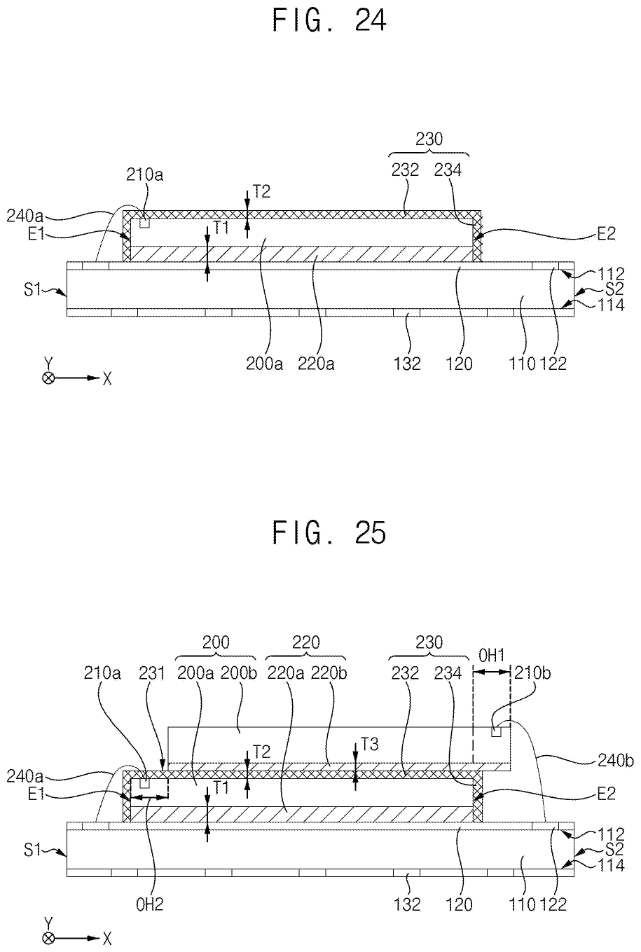

Referring to FIG. 24, processes the same as or similar to processes described with reference to FIGS. 13 to 16 may be performed to dispose a stress relieving adhesive layer 230 on the entire surface of the first semiconductor chip 200a, such as entirety of the upper and lateral side surfaces of the first semiconductor chip 200a.

In an embodiment, a liquid adhesive L may be dispensed onto the surface of the first semiconductor chip 200a while moving a dispenser nozzle 50 along the entire surface of the first semiconductor chip 200a. The liquid adhesive L may then be cured to form the stress relieving adhesive layer 230. Alternatively, the stress relieving adhesive layer 230 may be formed by a printing process.

The stress relieving adhesive layer 230 may cover the upper surface of the first semiconductor chip 200a and the first to fourth side surfaces E1, E2, E3, and E4 except for the bonding wires 240a connected to the first chip pads 210a. In an embodiment, the stress relieving adhesive layer 230 may include a first adhesive portion 232 covering the upper surface of the first semiconductor chip 200a and a second adhesive portion 234 extending vertically downward to the first insulating layer 120 to cover the first to fourth side surfaces E1, E2, E3, E4 of the first semiconductor chip 200a.

Referring to FIG. 24, processes that are the same as or similar to processes described with reference to FIG. 21 may be performed to attach a second semiconductor chip 200b to the stress relieving adhesive layer 230 on the first semiconductor chip 200a by a second adhesive film 220b, and a wire bonding process may be performed to connect second chip pads 210b of the second semiconductor chip 200b to the substrate pads 122 on the upper surface 112 of the package substrate 110 by bonding wires 240b.

In an embodiment, the second semiconductor chip 200b may be offset-aligned in a horizontal direction on the first semiconductor chip 200a. For example, the second semiconductor chip 200b may be offset-aligned in a second direction (e.g., the X direction) and a first direction (e.g., the Y direction) to expose the first chip pads 210a.

Accordingly, the second semiconductor chip 200b may have a first overhang region OH1 that protrudes from the second side surface E2 (or the fourth side surface E4) of the first semiconductor chip 200a, such as a protruding portion. In addition, the first semiconductor chip 200a may have a second overhang region OH2 that protrudes from the second semiconductor chip 200b, such as a protruding portion. The second semiconductor chip 200b may be offset-aligned in the horizontal direction on the first adhesive portion 232 to expose a peripheral portion 231 of the first adhesive portion 232 of the stress relieving adhesive layer 230.

In an embodiment, a process the same as or similar to processes described with reference to FIG. 21 may then be performed to form a molding member 300 on the upper surface 112 of the package substrate 110 to cover the first and second semiconductor chips 200a, 200b and the bonding wires 240a, 240b, and external connection members may be formed on external connection pads 132 on a lower surface 114 of the package substrate 110 to complete a semiconductor package 101 in FIG. 22.

FIG. 26 is a cross-sectional view illustrating a semiconductor package in accordance with an embodiment. FIG. 27 is a plan view illustrating the semiconductor package in FIG. 26. FIG. 26 is a cross-sectional view taken along the line I-I′ of FIG. 27. The semiconductor package is substantially the same as the semiconductor package described with reference to FIGS. 1 and 2, except for a stack structure of an additional control chip, additional spacer chips and semiconductor chips. Thus, same reference numerals will be used to refer to the same or similar elements and any further repetitive explanation concerning the above elements may be omitted for economy of description.

Referring to FIGS. 26 and 27, in an embodiment a semiconductor package 102 may include a package substrate 110, at least one control chip 500, spacer chips 150, a plurality of semiconductor chips 200, a stress relieving adhesive layer 230 and a molding member 300. The semiconductor package 102 may further include conductive connection members 240 that electrically connect the semiconductor chips 200 to the package substrate 110. In addition, the semiconductor package 102 may further include external connection members 400.

In an embodiment, the package substrate 110 may have a chip mounting region MR in the central region thereof. The chip mounting region MR may be a region in which the control chip 500 is mounted. In an embodiment, the chip mounting region MR may have a rectangular shape. The package substrate 110 may include first substrate pads 122 that are arranged along first and second side portions S1, S2 of the package substrate 110 and second substrate pads 124 that are arranged in the chip mounting region MR.

In an embodiment, the control chip 500 may be mounted on the chip mounting region MR of the package substrate 110. For example, in an embodiment the control chip 500 may be mounted on the package substrate 110 via conductive bumps 530. The control chip 500 may be arranged such that a front surface 502, such as an active surface thereof, on which chip pads 510 are formed faces the package substrate 110. The control chip 500 may have a rectangular shape having four side surfaces when viewed from a plan view (e.g., in a plane defined in the X and Y directions). The chip pads 510 may be arranged in an array on the entire front surface 502 of the control chip 500.

In an embodiment, the control chip 500 may be a logic chip including a logic circuit. The logic chip may be a controller controls memory chip. For example, the first semiconductor chip may be a processor ship such as ASIC, an application processor (AP), etc. serving as a host such as a CPU, GPU, or SOC.

In an embodiment, the control chip 500 may be mounted on the package substrate 110 by a flip chip bonding method. The chip pads 510 of the control chip 500 may be electrically connected to the second substrate pads 124 of the package substrate 110 by conductive bumps 530, for example, solder bumps.

In an embodiment, at least one spacer chip 150 may be arranged on the chip mounting region MR on the package substrate 110 to be spaced apart from the control chip 500. Two spacer chips 150 may be attached to be spaced apart from each other on the upper surface 112 of the package substrate 110 by adhesive films 152. The two spacer chips 150 may be spaced apart from each other in a first direction (e.g., the X direction) with the chip mounting region MR interposed therebetween.

In an embodiment, the plurality of semiconductor chips 200 may be stacked on the spacer chips 150 using adhesive films 220. The lowermost first semiconductor chip 200a of the plurality of semiconductor chips may be attached to the spacer chips 150 using a first adhesive film 220a. In an embodiment, the other semiconductor chips 200b, 200c, and 200d of the plurality of semiconductor chips may be sequentially attached on the lowermost first semiconductor chip 200a using second, third, and fourth adhesive films 220b, 220c and 220d. However, embodiments of the present disclosure are not necessarily limited thereto and the number of the semiconductor chips may vary.

In an embodiment, the semiconductor chip may include a memory chip including a memory circuit. For example, the first semiconductor chip may include volatile memory devices such as DRAM devices, SRAM devices, etc. or non-volatile memory devices such as flash memory devices, PRAM devices, MRAM devices, ReRAM devices, etc.

In an embodiment, the lowermost first semiconductor chip 200a may be attached on the spacer chips 150 and the control chip 500 using the first adhesive film 220a such as a die attach film (DAF) by the die attachment process. The first semiconductor chip 200a may be arranged such that a backside surface, such as an inactive surface, opposite to a front surface on which the first chip pads 210a are formed faces the package substrate 110. The first semiconductor chip 200a may have a rectangular shape having four side surfaces when viewed in a plan view (e.g., in a plane defined in the X and Y directions).

At least a portion of the spacer chip 150 arranged adjacent to a second side S2 of the package substrate 110 may be arranged to protrude from a second side surface E2 of the lowermost first semiconductor chip 200a. The protruding portion of the spacer chip 150 may be a portion at which the dispensing of a liquid adhesive for forming the stress relieving adhesive layer 230 ends.

In an embodiment, the stress relieving adhesive layer 230 may be attached to the upper surface and the second side surface E2 of the first semiconductor chip 200a. The stress relieving adhesive layer 230 may include a first adhesive portion 232 that covers the upper surface of the first semiconductor chip 200a and exposes the first chip pads 210a, and a second adhesive portion 234 that extends vertically downward from the first adhesive portion 232.

In an embodiment, the other semiconductor chips 200b, 200c, 200d among the plurality of semiconductor chips may be sequentially attached on the lowermost first semiconductor chip 200a by the second, third, and fourth adhesive films 220b, 220c, 220d.

The second semiconductor chip 200b may be attached on the stress relieving adhesive layer 230 on the first semiconductor chip 200a by the second adhesive film 220b. In an embodiment, the second semiconductor chip 200b may be attached to the first adhesive portion 232 of the stress relieving adhesive layer 230 using the second adhesive film 220b such as a die attach film (DAF) by a die attach process.

In an embodiment, the plurality of semiconductor chips 200a, 200b, 200c, 200d may be sequentially offset-aligned. For example, the semiconductor chips 200a, 200b, 200c, 200d may be stacked in a zigzag structure or a cascade structure. The semiconductor chips 200a, 200b, 200c, 200d may be sequentially offset-aligned in a first horizontal direction (e.g., the X direction) of the package substrate 110.

In an embodiment, the semiconductor chips 200 may be electrically connected to the package substrate 110 by the conductive connection members 240. The chip pads of the semiconductor chips 200 may be connected to the first substrate pads 122 on the upper surface 112 of the package substrate 110 by bonding wires 240.

In an embodiment, the molding member 300 may cover the spacer chips 150, the semiconductor chips 200, and the bonding wires 240 on the upper surface 112 of the package substrate 110. In an embodiment, the molding member may include a thermosetting resin, for example, an epoxy mold composite (EMC). However, embodiments of the present disclosure are not necessarily limited thereto.

In an embodiment, the stress relieving adhesive layer 230 may be attached to the upper surface and the second side surface E2 of the first semiconductor chip 200a. However, embodiments of the present disclosure are not necessarily limited thereto. For example, the stress relieving adhesive layer 230 may be attached to surfaces of the other semiconductor chips 200b, 200c, 200d. The stress relieving adhesive layer 230 may be locally formed on some surfaces of the semiconductor chips 200 where different materials meet.

FIG. 28 is a cross-sectional view illustrating a semiconductor package in accordance with an embodiment. FIG. 29 is an enlarged cross-sectional view illustrating portion ‘J’ in FIG. 28. The semiconductor package is substantially the same as the semiconductor package described with reference to FIGS. 1 and 2, except for a mounting method of a first semiconductor chip and a stack structure of second and third semiconductor chips. Thus, the same reference numerals will be used to refer to the same or similar elements and any further repetitive explanation concerning the above elements may be omitted for economy of description.

Referring to FIGS. 28 and 29, a semiconductor package 103 may include a package substrate 110, a first semiconductor chip 200a arranged on the package substrate 110, second and third semiconductor chips 200b and 200c arranged on the first semiconductor chip 200a, a stress relieving adhesive layer 230 covering an upper surface and at least one side surface of the first semiconductor chip 200a, and the molding member 300.

In an embodiment, the first semiconductor chip 200a may be mounted on a chip mounting region of the package substrate 110. For example in an embodiment, the first semiconductor chip 200a may be mounted on the package substrate 110 by a flip chip bonding method. In an embodiment, the first semiconductor chip 200a may be mounted on the package substrate 110 via first conductive connection members 240a such as conductive bumps. The first semiconductor chip 200a may be arranged such that a front surface on which first chip pads 210a are formed, such as an active surface, faces the package substrate 110. The first chip pads 210a may be arranged in an array on the entire front surface of the first semiconductor chip 200a. The first chip pads 210a of the first semiconductor chip 200a may be electrically connected to second substrate pads 124 of the package substrate 110 by the conductive bumps 240a, for example, solder bumps. An underfill member 222 may be disposed between the first semiconductor chip 200a and a package substrate 110.

In an embodiment, the first semiconductor chip 200a may have a rectangular shape having four side surfaces when viewed in a plan view (e.g., in a plane defined in the X and Y directions). The first semiconductor chip 200a may include a first side surface E1 and a second side surface E2 extending in a direction parallel to a first direction and facing each other, and a third side surface and a fourth side surface extending in a direction parallel to a second direction orthogonal to the first direction and facing each other.

In an embodiment, the stress relieving adhesive layer 230 may include a first stress relieving adhesive layer 230a that covers the upper surface and the first side surface E1 of the first semiconductor chip 200a under the second semiconductor chip 200b and a second stress relieving adhesive layer 230b that covers the upper surface and the second side surface E2 under the third semiconductor chip 200c. In an embodiment, the stress relieving adhesive layer 230 may include a die attach film DAF, a thermosetting resin, etc.

The first adhesive layer 230a may include a first adhesive portion 232 covering the upper surface of the first semiconductor chip 200a and a second adhesive portion 234 extending vertically downward from the first adhesive portion 232 to the first insulating layer 120 to cover the first side surface E1 of the first semiconductor chip 200a. The second stress relieving adhesive layer 230b may include a first adhesive portion 232 covering the upper surface of the first semiconductor chip 200a and a second adhesive portion 234 extending vertically downward from the first adhesive portion 232 to the insulating layer 120.

In an embodiment, the second semiconductor chip 200b may be attached on the first stress relieving adhesive layer 230a on the first semiconductor chip 200a by a second adhesive film 220b. In an embodiment, the second semiconductor chip 200b may be attached to the first adhesive portion 232 of the first stress relieving adhesive layer 230a using the second adhesive film 220b such as a die attach film (DAF) by a die attach process.

The second semiconductor chip 200b may have the first overhang region OH1 that protrudes from the first side surface E1 of the first semiconductor chip 200a. The second semiconductor chip 200b may be offset-aligned in a horizontal direction on the first adhesive portion 232 to expose a peripheral portion 231 of the first adhesive portion 232 of the first stress relieving adhesive layer 230a.

In an embodiment, the third semiconductor chip 200c may be attached on the second stress relieving adhesive layer 230b on the first semiconductor chip 200a by a third adhesive film 220c. The third semiconductor chip 200c may be attached to the first adhesive portion 232 of the second stress relieving adhesive layer 230b using the third adhesive film 220c such as a die attach film (DAF) by a die attach process.

The third semiconductor chip 200c may have a first overhang region OH1 that protrudes from the second side surface E2 of the first semiconductor chip 200a. In an embodiment, the third semiconductor chip 200c may be offset-aligned in a horizontal direction on the first adhesive portion 232 to expose a peripheral portion 231 of the first adhesive portion 232 of the second stress relieving adhesive layer 230b.

As illustrated in FIG. 29, the first semiconductor chip 200a may include a substrate 202 with circuit elements disposed on the front surface and a back insulating layer 206 on the backside surface of the substrate 202. For example, the back insulating layer 206 may include a single layer or a composite layer. When the first semiconductor chip 200a is individually separated by cutting a wafer by a dicing process, an edge portion between the upper surface (backside surface) and the first and second side surfaces E1, E2 of the first semiconductor chip 200a may be chipped, and thus, an upper edge portion of the back insulating layer 206 may have an inclined surface exposed to the outside.

The first and second stress relieving adhesive layers 230a, 230b may be formed to cover the inclined surface of the upper edge portion of the first semiconductor chip 200a under the first overhang region OH1 of each of the second and third semiconductor chips 200b, 200c. The upper edge portion of the first semiconductor chip 200a may not be in direct contact with the EMC of the molding member 300 and may be spaced apart from the molding member 300 by the stress relieving adhesive layer 230. Since the inclined surface of the upper edge portion of the first semiconductor chip 200a under the first overhang region OH1 is covered by the DAF of the stress relieving adhesive layer 230 that has a relatively large amount of hygroscopic expansion than EMC, the pressure of the stress relieving adhesive layer 230 pressing the upper edge portion of the back insulating layer 206 downward may be increased to prevent peeling-off due to a difference in the amount of hygroscopic expansion at the portion where different materials meet.

FIG. 30 is a cross-sectional view illustrating a semiconductor package in accordance with embodiments. FIG. 31 is an enlarged cross-sectional view illustrating portion ‘K’ in FIG. 30. The semiconductor package is substantially the same as the semiconductor package described with reference to FIGS. 28 and 29, except for a stack structure and a mounting method of the second and third semiconductor chips. Thus, same reference numerals will be used to refer to the same or similar elements and any further repetitive explanation concerning the above elements may be omitted for economy of description.

Referring to FIGS. 30 and 31, in an embodiment a semiconductor package 104 may include a package substrate 110, a first semiconductor chip 200a arranged on the package substrate 110, second and third semiconductor chips 200b, 200c arranged on the first semiconductor chip 200a to be spaced apart from each other, a stress relieving adhesive layer 230 covering the upper surface and at least one side surface of the first semiconductor chip 200a, and a molding member 300.

In an embodiment, the second semiconductor chip 200b may be arranged such that a front surface on which second chip pads 210b are formed, such as an active surface, faces the package substrate 110. The front surface of the second semiconductor chip 200b may be attached to a first adhesive portion 232 of the first stress relieving adhesive layer 230a. The second semiconductor chip 200b may have a first overhang region OH1 that protrudes from a first side surface E1 of the first semiconductor chip 200a. The second semiconductor chip 200b may be offset-aligned in a horizontal direction on the first adhesive portion 232 to expose a peripheral portion 231 of the first adhesive portion 232 of the first stress relieving adhesive layer 230a.

The second semiconductor chip 200b may be electrically connected to the package substrate 110 by first vertical conductive structures 240b such as through mold vias. The first vertical conductive structures 240b may extend upward from the substrate pads 122 of the package substrate 110 (e.g., in a vertical direction) to be connected to the second chip pads 210b. Accordingly, the second chip pads 210b of the second semiconductor chip 200b may be electrically connected to the substrate pads 122 on the upper surface 112 of the package substrate 110 by conductive connection members such as the first vertical conductive structures 240b (e.g., through mold vias).

The third semiconductor chip 200c may be arranged such that a front surface on which third chip pads 210c are formed, such as an active surface, faces the package substrate 110 (e.g., in a vertical direction). The front surface of the third semiconductor chip 200c may be attached to a first adhesive portion 232 of the second stress relieving adhesive layer 230b. The third semiconductor chip 200c may have a first overhang region OH1 that protrudes from the second side surface E2 of the first semiconductor chip 200a. The third semiconductor chip 200c may be offset-aligned in a horizontal direction on the first adhesive portion 232 to expose a peripheral portion 231 of the first adhesive portion 232 of the second stress relieving adhesive layer 230b.

The third semiconductor chip 200c may be electrically connected to the package substrate 110 by second vertical conductive structures 240c, such as through mold vias. The second vertical conductive structures 240c may extend upward from the substrate pads 122 of the package substrate 110 to be connected to the third chip pads 210c. Accordingly, the third chip pads 210c of the third semiconductor chip 200c may be electrically connected to the substrate pads 122 on the upper surface 112 of the package substrate 110 by conductive connection members such as the second vertical conductive structures 240c (e.g., through mold vias).

As illustrated in FIG. 31, in an embodiment the first semiconductor chip 200a may include a substrate 202 with circuit elements disposed on the front surface and a back insulating layer 206 on the backside surface of the substrate 202. For example, the back insulating layer 206 may include a single layer or a composite layer. When the first semiconductor chip 200a is individually separated by cutting a wafer by a dicing process, an edge portion between the upper surface (e.g., the backside) and the first and second side surfaces E1, E2 of the first semiconductor chip 200a may be chipped, and thus, an upper edge portion of the back insulating layer 206 may have an inclined surface exposed to the outside.

In an embodiment, the first and second stress relieving adhesive layers 230a, 230b may be formed to cover the inclined surface of the upper edge portion of the first semiconductor chip 200a under the first overhang region OH1 of each of the second and third semiconductor chips 200b, 200c. The upper edge portion of the first semiconductor chip 200a is not in direct contact with the EMC of the molding member 300 and is spaced apart from the molding member 300 by the stress relieving adhesive layer 230. The inclined surface of the upper edge portion of the first semiconductor chip 200a under the first overhang region OH1 is covered by the DAF of the stress relieving adhesive layer 230 that has a relatively large amount of hygroscopic expansion than EMC.

In an embodiment, a semiconductor package having a structure similar to the semiconductor package in FIG. 30 may be provided.

For example, the first vertical conductive structures 240b may be provided as first support structures that support the first overhang region OH1 of the second semiconductor chip 200b. In this embodiment, the second semiconductor chip 200b may be arranged such that a backside surface opposite to a front surface on which the second chip pads 210b are formed, faces the package substrate 110 (e.g., in a vertical direction), and the second chip pads 210b of the second semiconductor chip 200b may be electrically connected to the substrate pads on the upper surface 112 of the package substrate 110 by bonding wires.

Similarly, the second vertical conductive structures 240c may be provided as second support structures that support the first overhang region OH1 of the third semiconductor chip 200c. In this embodiment, the third semiconductor chip 200c may be arranged such that a backside surface opposite to a front surface on which the third chip pads 210c are formed, faces the package substrate 110 (e.g., in a vertical direction), and the third chip pads 210c of the third semiconductor chip 200c may be electrically connected to the substrate pads on the upper surface 112 of the package substrate 110 by bonding wires.

The semiconductor package may include semiconductor devices such as logic devices or memory devices. In an embodiment, the semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of embodiments and is not to be construed as limiting thereof. Although a few non-limiting embodiments have been described, those skilled in the art will readily appreciate that many modifications are possible in embodiments without materially departing from the novel teachings and advantages of the present disclosure. Accordingly, all such modifications are intended to be included within the scope of the present disclosure.

What is claimed is:

1. A semiconductor package, comprising:
a package substrate;
a first semiconductor chip arranged on an upper surface of the package substrate, the first semiconductor chip having a first side surface and a second side surface each extending in a first direction parallel to the upper surface of the package substrate and facing each other, the first semiconductor chip having first chip pads that are disposed on a first surface thereof and arranged along the first side surface;
a stress relieving adhesive layer disposed on the first semiconductor chip and covering the first semiconductor chip from the first surface of the first semiconductor chip to the second side surface of the first semiconductor chip and exposing the first chip pads;
a second semiconductor chip disposed on the stress relieving adhesive layer on the first semiconductor chip by an adhesive film, wherein the second semiconductor chip is offset-aligned with the first semiconductor chip in a second direction perpendicular to the first direction to expose the first chip pads; and
a molding member covering the first semiconductor chip and the second semiconductor chip on the package substrate.

2. The semiconductor package of claim 1, wherein the stress relieving adhesive layer includes a same material as the adhesive film.

3. The semiconductor package of claim 2, wherein the stress relieving adhesive layer includes a die attach film.

4. The semiconductor package of claim 1, wherein the stress relieving adhesive layer includes a same material as the molding member.

5. The semiconductor package of claim 1, wherein:
the stress relieving adhesive layer includes a first adhesive portion that covers the first surface of the first semiconductor chip and exposes the first chip pads; and
a second adhesive portion that covers the second side surface of the first semiconductor chip.

6. The semiconductor package of claim 5, wherein the second semiconductor chip is offset-aligned with the first semiconductor chip in the second direction on the first adhesive portion to expose a periphery portion of the first adhesive portion of the stress relieving adhesive layer.

7. The semiconductor package of claim 1, wherein:
the stress relieving adhesive layer has a thickness in a range of about 10 μm to about 30 μm; and
the adhesive film has a thickness in a range of about 10 μm to about 40 μm.

8. The semiconductor package of claim 1, wherein:
the first semiconductor chip has a third side surface and a fourth side surface that each extend in the second direction, and the first semiconductor chip further has additional first chip pads that are arranged along the third side surface;
the stress relieving adhesive layer is disposed on the first semiconductor chip and covers the first semiconductor chip from an upper surface of the first semiconductor chip to the fourth side surface, the stress relieving adhesive layer exposing the additional first chip pads; and
the second semiconductor chip is offset-aligned with the first semiconductor chip in the first direction to expose the additional first chip pads.

9. The semiconductor package of claim 1, further comprising:
at least one spacer chip disposed on the package substrate,
wherein the first semiconductor chip is arranged on the at least one spacer chip.

10. The semiconductor package of claim 1, further comprising:
at least one third semiconductor chip stacked on the second semiconductor chip by an adhesive film.

11. A semiconductor package, comprising:
a package substrate;
a first semiconductor chip disposed on the package substrate;
a second semiconductor chip disposed on the first semiconductor chip by an adhesive film, wherein the second semiconductor chip is offset-aligned with the first semiconductor chip in a horizontal direction;
a stress relieving adhesive layer disposed on the first semiconductor chip and covering an upper surface of the first semiconductor chip, the stress relieving adhesive layer extending vertically downward from the upper surface to cover a side surface of the first semiconductor chip under an overhang region of the second semiconductor chip; and
a molding member covering the first semiconductor chip and the second semiconductor chip on the package substate.

12. The semiconductor package of claim 11, wherein the stress relieving adhesive layer includes a same material as the adhesive film.

13. The semiconductor package of claim 12, wherein the stress relieving adhesive layer includes a die attach film.

14. The semiconductor package of claim 11, wherein the stress relieving adhesive layer includes a same material as the molding member.

15. The semiconductor package of claim 11, wherein:
the stress relieving adhesive layer includes a first adhesive portion that covers the upper surface of the first semiconductor chip and exposes the first chip pads; and
a second adhesive portion that covers the side surface of the first semiconductor chip.

16. The semiconductor package of claim 11, wherein the stress relieving adhesive layer is attached on an entirety of an upper surface of the first semiconductor chip and lateral side surfaces of the first semiconductor chip including the side surface except for portions of conductive connection members connected to the first chip pads.

17. The semiconductor package of claim 11, wherein:
the stress relieving adhesive layer has a thickness in a range of about 10 μm to about 30 μm; and
the adhesive film has a thickness in a range of about 10 μm to about 40 μm.

18. The semiconductor package of claim 11, further comprising:
at least one spacer chip attached on the package substrate,
wherein the first semiconductor chip is arranged on the at least one spacer chip.

19. The semiconductor package of claim 11, further comprising:
at least one third semiconductor chip stacked on the second semiconductor chip by an adhesive film.

20. A semiconductor package, comprising:
a package substrate;
a first semiconductor chip arranged on the package substrate, the first semiconductor chip having first chip pads that are disposed on a first surface thereof and arranged along a first side surface of the first semiconductor chip;
a stress relieving adhesive layer covering the first surface of the first semiconductor chip except for the first chip pads and extending vertically downward to cover a second side surface facing the first side surface of the first semiconductor chip;
a second semiconductor chip disposed on the stress relieving adhesive layer on the first semiconductor chip by an adhesive film, wherein the second semiconductor chip is offset-aligned with the first semiconductor chip in a horizontal direction from the first side surface to the second side surface such that the first chip pads are exposed by the second semiconductor chip; and
a molding member covering the first semiconductor chip and the second semiconductor chip on the package substrate,
wherein the stress relieving adhesive layer has a thickness in a range of about 10 μm to about 30 μm, and the adhesive film has a thickness in a range of about 10 μm to about 40 μm.
